(19) United States
(12) Patent Application Publication
(10) Pub. No.: US 2007/0023866 A1
(43) Pub. Date: Feb. 1, 2007

(54) VERTICAL SILICON CONTROLLED RECTIFIER ELECTRO-STATIC DISCHARGE PROTECTION DEVICE IN BI-CMOS TECHNOLOGY

(75) Inventors: Kiran V. Chatty, Williston, VT (US); Robert J. Gauthier Jr., Hinesburg, VT (US); Andreas D. Stricker, Essex Junction, VT (US); Min Woo, Milton, VT (US)

Correspondence Address: HOFFMAN, WARNICK & D'ALESSANDRO LLC, 75 STATE ST, 14TH FLOOR, ALBANY, NY, 12207, US

(73) Assignee: INTERNATIONAL BUSINESS MACHINES CORPORATION, Armonk, NY (US)

(21) Appl. No.: 11/161,230

(22) Filed: Jul. 27, 2005

(51) Int. Cl. H01L 27/082

(52) U.S. Cl. 257/575

(57) ABSTRACT

A vertical silicon controlled rectifier (SCR) that directs an electro-static discharge (ESD) current directly to ground from the input/output pad. The vertical SCR is includes a vertical NPN and a vertical PNP that creates a very good SCR exhibiting very low ohmic on-resistance. The vertical SCR provides a low on-resistance and fast turn on, and can be adjusted to alter the trigger voltage value, holding voltage and how it is triggered. It can be optimized to trigger under ESD events and discharge the ESD current effectively to ground.

### BACKGROUND OF THE INVENTION

1. Technical Field

The present invention relates generally to electrostatic discharge (ESD) protection devices, and more particularly, to a vertical silicon controlled rectifier (SCR) used as an ESD protection device in bipolar complementary metal oxide semiconductor (BiCMOS) technology.

2. Related Art

Electro-static discharge (ESD) protection devices are used in practically all electronic devices to protect circuitry. The design and application of ESD devices in circuits, however, has become more difficult because of the low voltage tolerance of the structures which have to be protected. More particularly, low trigger and holding voltages as well as very low on-state resistance are required for these low voltage tolerance structures. Unfortunately, the current ESD protection designs in silicon (Si) or in silicon-germanium (SiGe) feature diodes and triggered circuits which have high on state resistances and holding voltages. In particular, each technology generation exhibits increasing power bus resistance, which makes it harder to implement positive mode ESD protection. One approach to address this situation is to use an ESD protection device or network that turns on in a positive mode, directing the ESD current directly to ground from the input/output pad. In this approach, one or more diodes are used to provide ESD protection. One shortcoming of conventional approaches, however, is that they use a parasitic lateral PNP device, which has a high ohmic resistance and low gain. Furthermore, the conventional approaches are not adjustable (tunable) in terms of how they are triggered or the trigger value.

In view of the foregoing, there is a need for an improved ESD protection device.

### SUMMARY OF THE INVENTION

The invention includes a vertical silicon controlled rectifier (SCR) that directs the ESD current directly to ground from the input/output pad. The vertical SCR includes a vertical NPN and a vertical PNP that creates a very good SCR exhibiting very low ohmic on-resistance. The vertical SCR provides a low on-resistance and fast turn on, and can be adjusted to alter the trigger voltage value, holding voltage and how it is triggered. It can be optimized to trigger under ESD events and discharge the ESD current effectively to ground.

A first aspect of the invention is directed to a silicon controlled rectifier (SCR) comprising: two vertical bipolar transistors stacked on each other, a first transistor including an emitter region formed by an out-diffusion from an in-situ doped emitter layer and a collector region having a dopant concentration tailored to provide a predetermined SCR characteristic.

A second aspect of the invention includes an electro-static discharge (ESD) protection device comprising: a silicon controlled rectifier (SCR) including two vertical bipolar transistors stacked on each other, a first transistor including an emitter region formed from an out-diffused emitter layer and a collector region having a dopant concentration tailored to provide a predetermined SCR characteristic.

A third aspect of the invention related to a method of forming an electrostatic discharge (ESD) protection device, the method comprising the steps of: forming a vertical bipolar junction transistor and a parasitic counterpart in a silicon-germanium layer; and optimizing a sub-collector and an isolation layer during the forming step to form a silicon-controlled rectifier (SCR) suitable for use as the ESD protection device.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows a schematic illustration of a silicon controlled rectifier (SCR) electro-static discharge (ESD) protection device according to the invention.

FIG. 2 shows a current-voltage characteristic curve for the SCR of FIG. 1.

FIG. 3 shows a first embodiment of the SCR of FIG. 1.

FIG. 4 shows a second embodiment of the SCR of FIG. 1.

FIGS. 5A-C shows a number of different embodiments for implementing an SCR of FIG. 1.

### DETAILED DESCRIPTION

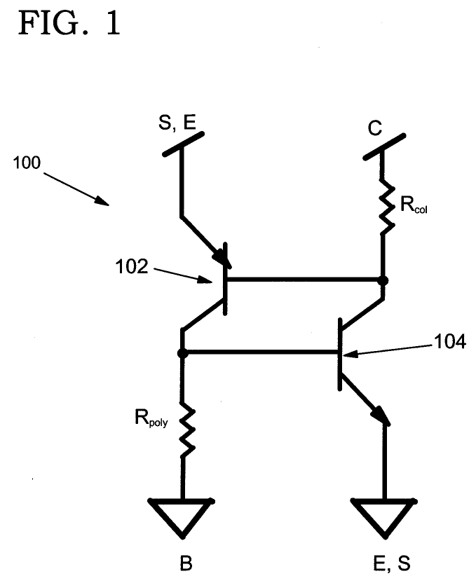

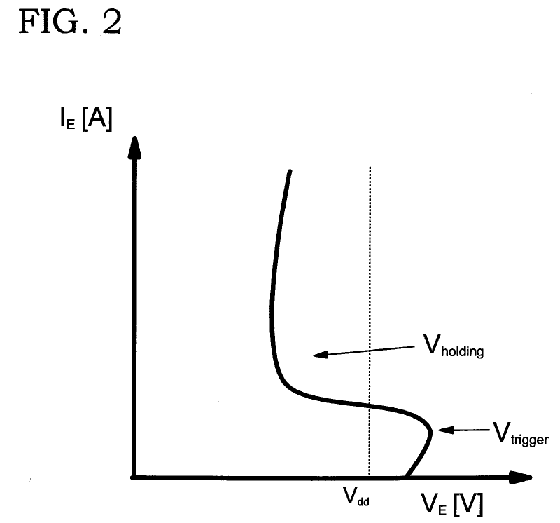

With reference to the accompanying drawings, FIG. 1 shows a schematic illustration of a silicon controlled register (SCR) 100 (also known as a thyristor) according to the invention, which can be used as an electrostatic discharge (ESD) protection device. SCR 100 includes two vertical bipolar transistors 102, 104 stacked on each other. In the drawings, ‘S’ indicates a substrate contact, ‘C’ indicates a collector contact, ‘B’ indicates a base contact, and ‘E’ indicates an emitter contact. Also, R_{poly} indicates resistance of a polysilicon region, and R_{col} indicates resistance of a collector region. FIG. 2 shows a current-voltage (IV) characteristics curve for SCR 100.

In S. M. Sze, Semiconductor Devices—Physics and Technology, 1^{st} edition, John Wiley, New York, 1985, Chapter 4.5, p. 145 and 149, characteristics of an ideal SCR are discussed. For example, an ideal SCR has a highly doped anode (P) region (e.g., ˜1×10¹⁹ dopant/cm³ impurity concentration), a lower doped N region (e.g. ˜1×10¹⁴), a medium doped P region (e.g., ˜1×10¹⁷) and a highly doped cathode (N) region (e.g., ˜1×10²⁰). An ideal SCR also has a current-voltage (IV) characteristic that includes a forward blocking region with a V_{BF} trigger point with a low ohmic (typically a value less than 1 Ohm) forward conducting stage (i.e., starting at Iₕ). SCR 100 for use as an ESD protection device is optimized to exhibit the above-described ideal characteristics.

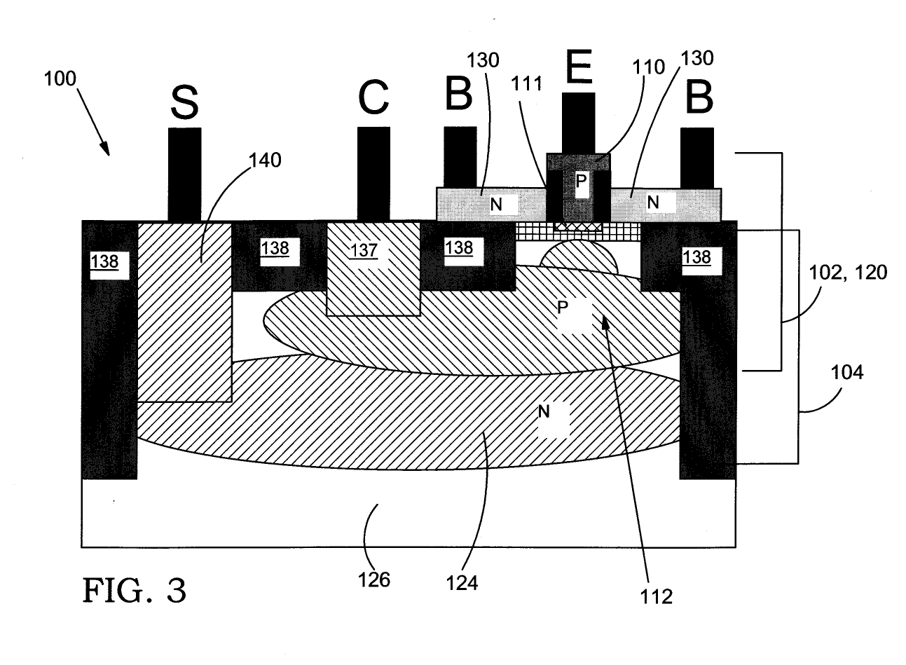

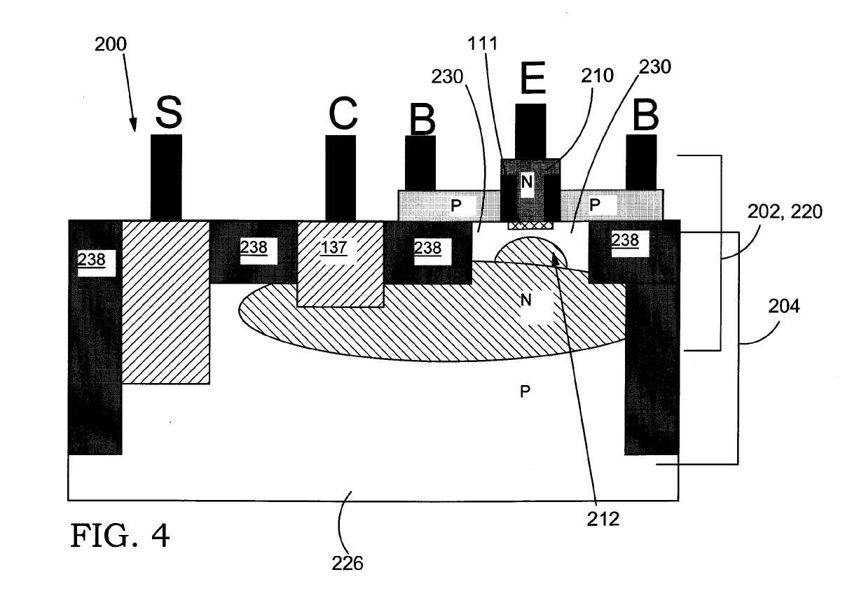

Turning to FIGS. 3-4, a cross-sectional view of two embodiments of an SCR 100, 200, respectively, are shown. In either embodiment, SCR 100, 200 includes a first transistor 102, 202 including an emitter region 110, 210 formed by out-diffusion from an in-situ doped emitter layer 111, and a selectively-implanted collector region 112, 212 having a dopant concentration tailored to provide a predetermined SCR characteristic, e.g., the characteristic(s) described in the previous paragraph. Out-diffused emitter layer may be formed by depositing a doped layer upon an undoped layer and annealing to diffuse dopant, i.e., not implanted directly. In one embodiment, the dopant concentration is approximately 1×10¹⁷ cm⁻³. First transistor 102, 202 is designed to have a good gain (β), e.g., greater than approximately 20.

Referring to FIG. 3, in one embodiment, SCR 100 is implemented as a PNPN structure including first transistor 102 in the form of a vertical PNP structure 120 and an isolation region 124 formed below collector region 112 to isolate second transistor 104 from a substrate 126. In this case, first transistor 102 includes a p-type emitter 110, an n-type base 130 and collector region 112, which is p-type. Also, second transistor 104 includes the n-type base region 130 as the collector, the p-type collector region 112 as the base, and the isolation region 124, which is n-type, as the emitter. Shallow trench or deep trench isolations 138 laterally separate components. Terminals of SCR 100 include p-type isolation region 124 (via well 140 and contact S), p-type collector region 112 via contact C (via reach through 137), n-type base region 130 via contacts B and p-type emitter 110 via contact E.

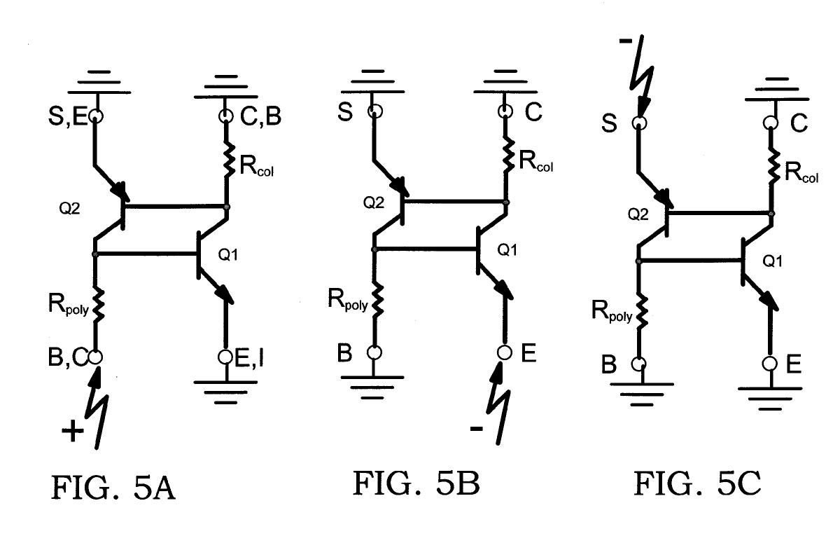

Referring to FIG. 4, in an alternative, preferred embodiment, a SCR 200 is implemented as a NPNP structure including first transistor 202 in the form of a vertical NPN structure 220. Here, substrate 226 includes a p-type dopant to form second transistor 204. First transistor 202 includes a vertical NPN structure 220 including a silicon-germanium (SiGe) base region 230. More specifically, first transistor 202 includes an out diffused n-type emitter 210, SiGe base region 230, which is p-type, and a collector region 212, which is n-type. Second transistor 204 includes the p-type SiGe base region 230 as the collector, the n-type collector region 212 as the base, and the p-type substrate 226 as the emitter. Terminals of SCR 200 include p-type substrate 226 via contact S, n-type collector region 212 via contact C (and reach through 137), p-type base region 230 via contacts B and n-type emitter 210 via contact E. In this embodiment, in response to an electro-static discharge (ESD), p-type substrate 226, n-type collector region 212 and p-type SiGe base region 230 are grounded, and n-type emitter 210 is shorted to a path of the ESD pulse (FIG. 5B).

The invention also includes a method of forming an ESD protection device. In a first step, a vertical bipolar junction transistor and a parasitic counterpart are formed in a silicon-germanium (SiGe) layer in any now known or later developed fashion. However, during formation, a sub-collector 112, 212 and an isolation layer 124 (FIG. 3) are optimized to form an SCR 100 suitable for use as the ESD protection device. The optimizing step may include a variety of different steps. In one embodiment, the optimizing step includes adjusting a layout of vertical bipolar transistor 104. In one embodiment, the spacing between a base region 130 and emitter 110 of vertical bipolar junction transistor 104 may be adjusted. In an alternative embodiment, the optimizing step may include adjusting a dopant concentration of collector region 112 and base region 130 of vertical bipolar junction transistor 104 to adjust a trigger voltage and a holding voltage.

FIGS. 5A-C illustrate schematic representations of different modes of implementation for the above-described vertical SCR 100, 200. For purposes of description, transistor Q1 is the vertical NPN and transistor Q2 is the vertical PNP. As shown the FIG. 5A, the base of Q2 is closely related to the base of Q1, which share the same diffusion layer. The middle diffusion layers, i.e., bases of Q1 and Q2, are connected to either path or ground via R_{col} or R_{poly}. As a result, the trigger of the SCR 100, 200 can be adjusted by altering the dimensions or the specific resistances of the layers. Second transistor Q2 has a good gain, which amplifies the current to turn on Q1. The gain of Q2 that is optimized by the invention determines how fast the SCR turns on. In FIG. 5A, a positive ESD pulse can be applied to base or collector contact B, C to trigger the device. In FIG. 5B, a negative ESD pulse can be applied to emitter contact E to trigger the device. In FIG. 5C, a negative ESD pulse can be applied to the contact S (substrate) to trigger the device. FIG. 5A is a preferred mode such that R_{poly} is the tunable feature.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. A silicon controlled rectifier (SCR) comprising:
two vertical bipolar transistors stacked on each other, a first transistor including an emitter region formed by an out-diffusion from an in-situ doped emitter layer and a collector region having a dopant concentration tailored to provide a predetermined SCR characteristic.

2. The SCR of claim 1, wherein the first transistor includes a PNP structure, and further comprising an isolation region formed below the collector region to isolate the second transistor from a substrate.

3. The SCR of claim 2, wherein the first transistor includes a p-type emitter, an n-type base and the collector region which is p-type, and the second transistor includes the n-type base region, the p-type collector region and the isolation region which is n-type.

4. The SCR of claim 3, wherein terminals of the SCR include the p-type isolation region, the p-type collector region, the n-type base region and the p-type emitter.

5. The SCR of claim 1, wherein the first transistor includes a vertical NPN structure including a silicon-germanium (SiGe) base region.

6. The SCR of claim 5, wherein the first transistor includes an n-type emitter, the SiGe base region which is p-type and the collector region which is n-type, and the second transistor includes the p-type SiGe base region, the n-type collector region and a p-type substrate.

7. The SCR of claim 6, wherein terminals of the SCR include the p-type substrate, the n-type collector region, the p-type base region and the n-type emitter.

8. The SCR of claim 6, wherein, in response to an electro-static discharge (ESD), the p-type substrate, the n-type collector region and the p-type SiGe base region are grounded, and the n-type emitter is shorted to a path of the ESD.

9. The SCR of claim 1, wherein each bipolar transistor has a gain of greater than approximately 20.

10. An electro-static discharge (ESD) protection device comprising:
a silicon controlled rectifier (SCR) including two vertical bipolar transistors stacked on each other, a first transistor including an emitter region formed from an out-diffused emitter layer and a collector region having a dopant concentration tailored to provide a predetermined SCR characteristic.

11. The ESD protection device of claim 10, wherein the first transistor includes a PNP structure, and further comprising an isolation region formed below the collector region to isolate the second transistor from a substrate.

12. The ESD protection device of claim 11, wherein the first transistor includes a p-type emitter, an n-type base and the collector region which is p-type, and the second transistor includes the n-type base region, the p-type collector region and the impurity region which is n-type.

13. The ESD protection device of claim 10, wherein the first transistor includes a vertical NPN structure including a silicon-germanium (SiGe) base region.

14. The ESD protection device of claim 13, wherein the first transistor includes an n-type emitter, the SiGe base region which is p-type and an n-type collector, and the second transistor includes the p-type SiGe base region, the n-type collector and a p-type substrate.

15. The ESD protection device of claim 10, wherein the collector region includes a base region of the second transistor.

16. The ESD protection device of claim 10, wherein current flow is substantially vertical.

17. A method of forming an electro-static discharge (ESD) protection device, the method comprising the steps of:
forming a vertical bipolar junction transistor and a parasitic counterpart in a silicon-germanium layer; and
optimizing a sub-collector and an isolation layer during the forming step to form a silicon-controlled rectifier (SCR) suitable for use as the ESD protection device.

18. The method of claim 17, wherein the optimizing step includes adjusting a layout of the vertical bipolar transistor.

19. The method of claim 18, wherein the adjusting step includes adjusting a spacing between a base region and an emitter of the vertical bipolar junction transistor.

20. The method of claim 17, wherein the optimizing step includes adjusting a dopant concentration of a collector region and a base region of the vertical bipolar junction transistor to adjust a trigger voltage and a holding voltage.
